(19) United States
(12) Patent Application Publication
(10) Pub. No.: US 2014/0332513 A1
(43) Pub. Date: Nov. 13, 2014

(54) DEVICE FOR DRILLING A SUBSTRATE AND A METHOD FOR DRILLING A SUBSTRATE

(71) Applicant: ASAHI GLASS COMPANY, LIMITED, Tokyo (JP)

(72) Inventor: Leander DITTMANN, Lausanne (CH)

(21) Appl. No.: 14/445,838

(22) Filed: Jul. 29, 2014

Related U.S. Application Data
(63) Continuation of application No. PCT/JP2013/051681, filed on Jan. 21, 2013.

(30) Foreign Application Priority Data
Feb. 10, 2012 (EP) 12154934.9

(51) Int. Cl. B23K 26/38; B23K 26/16; H01L 21/67; H01L 21/268; H01L 21/263

(52) U.S. Cl. CPC B23K 26/381; H01L 21/268; H01L 21/2633; H01L 21/67115; B23K 26/16
USPC 219/121.71; 219/121.7

(57) ABSTRACT

A device is used for drilling a substrate, in particular a device for generating a hole or recess or well in an electrically insulating or semiconducting substrate, more specifically a device for generating a plurality of holes or recesses or wells in an electrically insulating or semiconducting substrate.

### CROSS-REFERENCE TO RELATED APPLICATIONS

This application is a continuation application filed under 35 U.S.C. 111(a) claiming the benefit under 35 U.S.C. 120 and 365(c) of a PCT International Application No. PCT/JP2013/051681 filed on Jan. 21, 2013 and designated the U.S., which is based upon and claims the benefit of priority of European Patent Application No. 12154934.9 filed on Feb. 10, 2012, the entire contents of which are incorporated herein by reference.

### BACKGROUND OF THE INVENTION

1. Field of the Invention

The present invention relates to a device for drilling a substrate, in particular a device for generating a hole or recess or well in an electrically insulating or semiconducting substrate, more specifically a device for generating a plurality of holes or recesses or wells in an electrically insulating or semiconducting substrate. The present invention also relates to a method for drilling a substrate, in particular a method for generating a hole or recess or well in an electrically insulating or semiconducting substrate, more specifically for generating a plurality of holes or recesses or wells in an electrically insulating or semiconducting substrate. Furthermore, the present invention relates to a use of the device for drilling a substrate.

2. Description of the Related Art

WO 2005/097439 and WO 2009/059786 disclose methods of generating structures in substrates using the intermittent application of voltages to a substrate typically using a switch. The holes of these earlier applications, when present in arrays, typically require large distances (typically >1 mm) between adjacent holes to avoid flashovers during production of arrays without insulating layers. WO 2011/038788 and WO 2010/063462 disclose methods of generating structures in substrates using the application of voltages to a substrate which allow the fabrication of arrays of holes with small pitch (typically <1 mm). These methods are limited in speed for producing multiple holes due to the necessary recharging of the high voltage capacitors to an energy required to open the hole and due to the maximum (intrinsic) switching rate of the switch. Therefore, there exists a need in the art to increase the rate at which electrical energy can be supplied to a substrate, for example in the generation of arrays of structures or holes.

### SUMMARY OF THE INVENTION

Accordingly, it is an object in one embodiment of the present invention to provide for a device and method for drilling a substrate, in particular for generating a plurality of holes or recesses or wells in a substrate which can be performed at a high speed of e.g. more than 10 holes per second (i.e. a repetition rate of 10 s⁻¹, i.e. a hole being produced in less than 100 ms), preferably even faster with a speed of more than 100 holes per second (i.e. a repetition rate of 100 s⁻¹, i.e. a hole being produced in less than 10 ms).

### BRIEF DESCRIPTION OF THE DRAWINGS

FIG. 1 shows a general setup of a device in accordance with one embodiment of the present invention;

FIGS. 2A and 2B show alternative representations of FIG. 1; and

FIGS. 3A and 3B show other representations of the embodiments of FIGS. 2A and 2B.

### DESCRIPTION OF THE PREFERRED EMBODIMENTS

The object in one embodiment of the present invention may be solved by a device for drilling an electrically insulating or semiconducting substrate, in particular for generating a plurality of holes or recesses or wells in the substrate, said device comprising:

an AC voltage source,

a DC voltage source,

a first electrode and a second electrode,

a user-programmable timing and control unit,

a mechanism to hold a substrate,

a laser,

said first electrode being a ground electrode, said second electrode being a voltage electrode for applying a voltage to a substrate,

said AC voltage source being connected to said second electrode;

said DC voltage source having a DC voltage output also connected to said second electrode, said DC voltage source comprising a plurality of DC voltage supplies and a plurality of switches, each DC voltage supply comprising a capacitor for storing a discrete amount of electrical energy, each DC voltage supply having a switch allocated which is selected from said plurality of switches, each DC voltage supply being connected to said DC voltage output via its own allocated switch, such that said DC voltage output of said DC voltage source is fed by said plurality of DC voltage supplies which are connected thereto by said plurality of switches in parallel,

said laser, said AC voltage source, said DC voltage source and said plurality of switches being connected to and controlled by said timing and control unit.

In one embodiment, said plurality of switches allow the application of a DC voltage from any of said DC voltage supplies to a substrate at a rate that is higher than the switching rate, preferably higher than the maximum switching rate, of a single switch.

In one embodiment, said plurality of switches are switches of the same type.

In one embodiment, said plurality of switches are triggered spark gaps, reed relays, thyratrons, ignitrons, or thyristors etc.

In one embodiment, said voltage applied via said second electrode is an AC voltage, a DC voltage or a combination of the two.

In one embodiment, said first electrode and said second electrode are located such that a substrate that is held by said mechanism to hold a substrate is located between said first electrode and second electrode.

In one embodiment said first electrode is a pointed electrode.

In another embodiment said first electrode is not pointed and, preferably, has a flat planar surface.

In one embodiment, said first electrode is part of said mechanism to hold a substrate.

In one embodiment, said rate at which a DC voltage is applied to said substrate is at least 1.2 times, preferably at least 1.5 times, 2 times, 3 times or 4 times, more preferably at least 5 times, even more preferably at least 6, 7, 8, 9 or 10 times faster than the maximum switching rate of a single switch of the same type as said plurality of switches.

In one embodiment, said rate at which a DC voltage is applied to the substrate is >1 ms⁻¹, preferably >2, >3, >4, >5, >6, >7, >8, >9, or >10 ms ⁻¹.

The objects in embodiments of the present invention are also solved by the use of a device according to one embodiment of the present invention, for drilling a substrate, in particular an electrically insulating or semiconducting substrate.

The object in one embodiment of the present invention may also be solved by a method of drilling a substrate, in particular of generating a plurality of holes or recesses or wells in a substrate, using the device according to one embodiment of the present invention, said method comprising the steps:

a) providing the device according to one embodiment of the present invention and a substrate which is electrically insulating or semiconducting at room temperature, placed in said mechanism to hold a substrate between said first and second electrodes,

b) melting a volume of material of said substrate by heating said volume using said laser and/or an AC voltage applied to said substrate, said volume extending fully or partially from a first surface of said substrate to a second surface of said substrate, said second surface being opposite said first surface,

c) removing the molten volume of material resulting from step b) by applying a DC voltage across said substrate using said second electrode connected to said DC voltage output and placed at a distance from and on opposite sides of said substrate, thereby applying a defined amount of electrical energy to the substrate and dissipating said electrical energy from said substrate,

d) moving the substrate by a defined distance and

e) repeating steps b)-d) n-times, wherein n>1, preferably n>100, 1000, 10000, 100000, 1000000, 5000000 or 10000000 and wherein the rate of repetition in step e) is defined by the rate of application of said DC voltage to said substrate in step c).

The present inventors have found that in comparison to the prior art methods and devices, the rates at which hole opening DC-voltages are supplied can still be increased and improved such that a higher speed can be achieved when for example arrays of holes are produced. This is achieved in accordance with one embodiment of the present invention by a parallelization of a plurality of DC-voltage supplies. In accordance with embodiments of the present invention, the DC-voltage source comprises a plurality of DC-voltage supplies all of which are connected in parallel to the output of the DC-voltage source via a plurality of switches in parallel. Each of the DC-voltage supplies has its own allocated switch, and each of said DC voltage supplies are connected to the output of the DC-voltage source by way of its allocated switch. By appropriately controlling the parallel switches, an extremely high rate of DC-voltage discharges can be achieved whereby DC-voltage application at a given time occurs through one of the plurality of switches. By controlling the plurality of switches in such a manner that the parallel switches are in an on-state in an offset manner, substantially higher rates of DC-voltage application can be achieved than if only a single switch and a single DC-voltage supply was used. This is because a single switch has inherent limitations in terms of its switching capability, due to its intrinsic switching rate/recovery rate. By choosing an appropriate number of switches and by an appropriate parallelization of these switches, each connecting its individual DC-voltage supply to the output of the DC-voltage source, a supply rate of DC-voltage can be achieved which is substantially higher than the individual maximum switching rate of a single switch.

Control of the switches as well as of the DC-voltage supplies and thus of the DC-voltage source, as well as of the AC-voltage source is achieved by the timing and control unit which, typically, is user-definable or user-programmable. Thus, a user can decide and determine if a pure AC-voltage, a pure DC-voltage or a superposition of the two is applied via the second electrode to a substrate. Furthermore, a user can define and determine at which rate a DC-voltage is applied, by appropriately timing the switches in an offset manner such that their respective on-states are timed such as to apply a DC-voltage (from different DC-voltage supplies) at a considerably higher rate than if just a single DC-voltage supply were to be used.

The term “a plurality of”, as used herein, is meant to refer to at least two, preferably at least 10, preferably at least 20, more preferably at least 50 units, e.g. switches, DC-voltage supplies etc.

The term “AC-voltage source” is meant to refer to a voltage source capable of generating an AC-voltage, preferably at high frequency. The term “AC-voltage source”, as used herein, is used synonymously and interchangeably with expressions like “high frequency generator”, “HF generator”, and “HFHV source” (HF=high frequency; HV=high voltage). The term “DC-voltage source” is meant to refer to a voltage source capable of generating a DC-voltage. In embodiments of the present invention, a DC-voltage source comprises a plurality of DC-voltage supplies. The DC-voltage source in accordance with embodiments of the present invention has a DC-voltage output, and, within the DC-voltage source according to embodiments of the present invention, there is a plurality of DC-voltage supplies, each of which is connected to the DC-voltage output, and the DC-voltage supplies are connected in parallel to said DC-voltage output via their respective allocated switches. Switching between the different DC-voltage supplies can be achieved via the respective switches of which there is one allocated each to each DC-voltage supply. Hence, the plurality of DC-voltage supplies is equalled by a plurality of switches out of which a switch is allocated each to each DC-voltage supply. Typically, in accordance with embodiments of the present invention, the plurality of switches comprise only switches of the same type. In preferred embodiments, the plurality of switches are triggered spark gaps.

Using the plurality of switches and plurality of DC-voltage supplies in a parallelized fashion, it has become possible to substantially increase the rates at which a DC-voltage can be applied to a substrate.

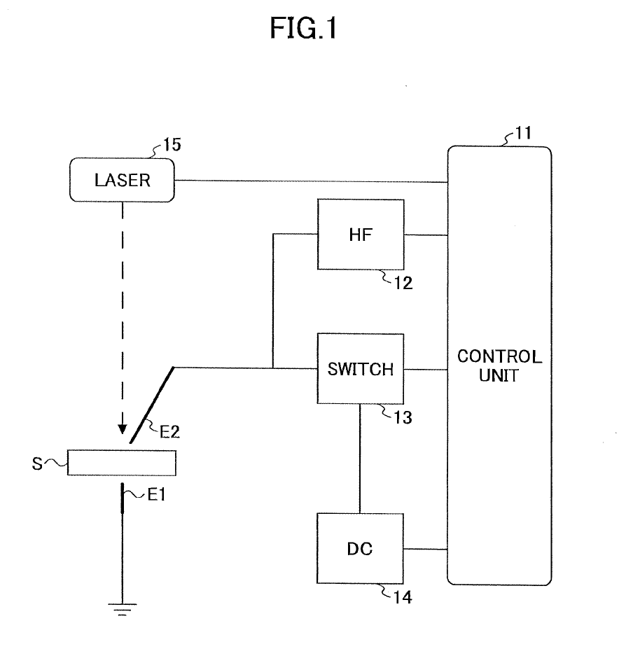

In the following, reference is now made to the figures, wherein FIG. 1 shows a general setup of a device in accordance with one embodiment of the present invention showing a laser 15, a DC-voltage source 14 and a high frequency high voltage source (“HF”) 12, each of which is connected to a control unit 11, and switching is achieved by a switch 13. E1 and E2 represent first and second electrodes, respectively. S represents a substrate. The substrate S is irradiated with laser light emitted from the laser 15.

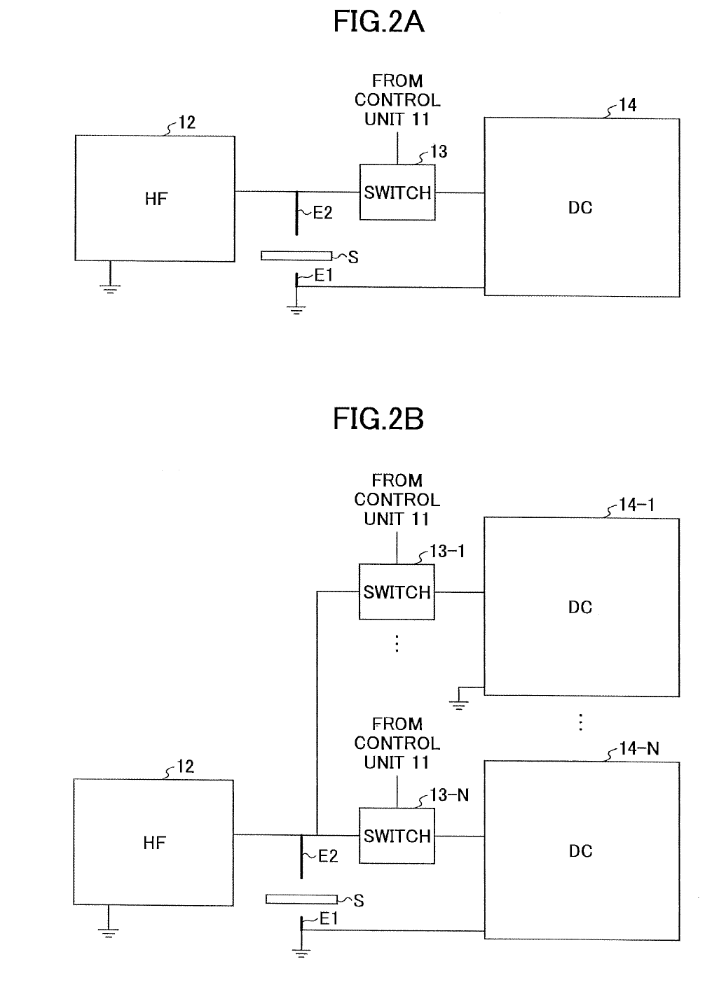

FIGS. 2A and 2B show alternative representations of FIG. 1, wherein FIG. 2A shows only a single DC-voltage source 14, whereas, in FIG. 2B, in accordance with embodiments of the present invention, a parallelized version of two or more DC-voltage supplies 14-1 to 14-N (N>1) is shown, including two or more parallel switches 13-1 to 13-N. The HF source 12 may include a couple capacitor. Each DC-voltage source 14 may include a storage capacitor, and inductive, dissipative and/or capacitive circuit components like L, R, and C.

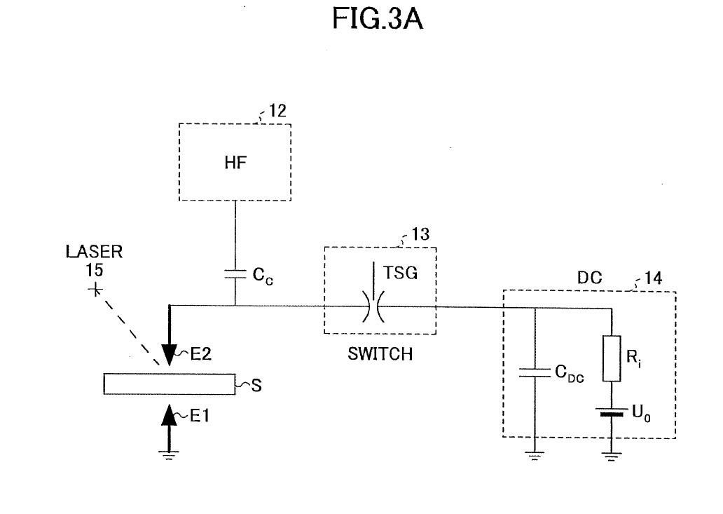

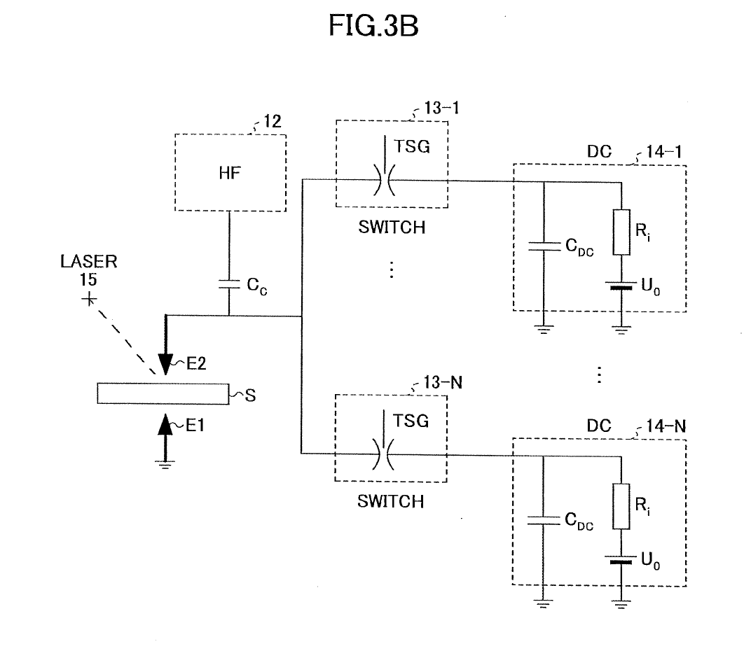

FIGS. 3A and 3B show other representations of the embodiments of FIGS. 2A and 2B, with more detail provided “TSG” is an abbreviation for “triggered spark gap”. U₀ represents the actual voltage source of the DC voltage supply, C_{DC} is the high voltage capacitor that is charged by the voltage source to an energy required to open the hole, Rᵢ represents the internal impedance of the voltage supply, E1 and E2 represent first and second electrodes, respectively, S represents a substrate, HF means high frequency high voltage source. C_{c} represents a couple HF capacitor.

The features of the embodiments of the present invention disclosed in the specification, the claims and/or in the accompanying drawings, may, both separately, and in any combination thereof, be material for realizing the invention in various forms thereof.

The embodiments of the present invention may be suitably applied to forming holes or recesses or wells in an electrically insulating or semiconducting substrate by laser drilling.

What is claimed is:

1. A device for drilling an electrically insulating or semiconducting substrate to generate a plurality of holes or recesses or wells in the substrate, said device comprising:
an AC voltage source;
a DC voltage source;
a first electrode and a second electrode;
a user-programmable timing and control unit; and
a laser,
said first electrode being a ground electrode, said second electrode being a voltage electrode for applying a voltage to a substrate,
said AC voltage source being connected to said second electrode;
said DC voltage source having a DC voltage output also connected to said second electrode, said DC voltage source comprising a plurality of DC voltage supplies and a plurality of switches, each DC voltage supply comprising a capacitor for storing a discrete amount of electrical energy, each DC voltage supply having a switch allocated which is selected from said plurality of switches, each DC voltage supply being connected to said DC voltage output via its own allocated switch, such that said DC voltage output of said DC voltage source is fed by said plurality of DC voltage supplies which are connected thereto by said plurality of switches in parallel,
said laser, said AC voltage source, said DC voltage source and said plurality of switches being connected to and controlled by said timing and control unit.

2. The device according to claim 1, wherein said plurality of switches allow the application of a DC voltage from any of said DC voltage supplies to a substrate at a rate that is higher than the switching rate of a single switch.

3. The device according to claim 1, wherein said plurality of switches are switches of the same type.

4. The device according to claim 1, wherein said plurality of switches are triggered spark gaps, reed relays, thyratrons, ignitrons or thyristors.

5. The device according to claim 1, wherein said voltage applied via said second electrode is an AC voltage, a DC voltage or a combination of the two.

6. The device according to claim 1, wherein said first electrode and said second electrode are located such that a substrate that is held by a mechanism to hold a substrate is located between said first electrode and second electrode.

7. The device according to claim 1, wherein said first electrode is a pointed electrode.

8. The device according to claim 1, wherein said first electrode is not pointed and, has a flat planar surface.

9. The device according to claim 6, wherein the first electrode is part of said mechanism to hold a substrate.

10. The device according to claim 2, wherein said rate at which a DC voltage is applied to said substrate is at least 1.2 times, preferably at least 1.5 times, preferably at least 2 times, more preferably at least 4 times, more preferably at least 5 times, even more preferably at least 6, 7, 8, 9, or 10 times faster than the maximum switching rate of a single switch of the same type as said plurality of switches.

11. Use of a device according to claim 1, for drilling a substrate, in particular an electrically insulating or semiconducting substrate.

12. A method of drilling a substrate to generate a plurality of holes or recesses or wells in a substrate, using the device according to claim 1, said method comprising the steps:
a) providing the device according to claim 1 and a substrate which is electrically insulating or semiconducting at room temperature, placed between said first and second electrodes;
b) melting a volume of material of said substrate by heating said volume using said laser and/or an AC voltage applied to said substrate, said volume extending fully or partially from a first surface of said substrate to a second surface of said substrate, said second surface being opposite said first surface;
c) removing the molten volume of material resulting from step b) by applying a DC voltage across said substrate using said second electrode connected to said DC voltage output and placed at a distance from and on opposite sides of said substrate, thereby applying a defined amount of electrical energy to the substrate and dissipating said electrical energy from said substrate;
d) moving the substrate by a defined distance; and
e) repeating steps b)-d) n-times, wherein n>1, preferably n>100, 1000, 10000, 100000, 1000000, 5000000 or 10000000, and wherein the rate of repetition in step e) is defined by the rate of application of said DC voltage to said substrate in step c).
